(19) United States
(12) Patent Application Publication
(10) Pub. No.: US 2026/0144083 A1
(43) Pub. Date: May 21, 2026

(54) METHOD OF MANUFACTURING PACKAGING SUBSTRATE

(71) Applicant: Absolics Inc., Covington, GA (US)

(72) Inventor: DAE HWAN KIM, Covington, GA (US)

(73) Assignee: Absolics Inc., Covington, GA (US)

(21) Appl. No.: 19/389,057

(22) Filed: Nov. 14, 2025

Related U.S. Application Data
(60) Provisional application No. 63/721,549, filed on Nov. 17, 2024.

(51) Int. Cl. H01L 21/48; C23C 14/02; C23C 14/34; H01J 37/32

(52) U.S. Cl. CPC H10W 70/05; C23C 14/022; C23C 14/34; H01J 37/32816; H01J 2237/336

(57) ABSTRACT

A method of manufacturing a packaging substrate according to the present disclosure manufactures a packaging substrate by including a preparation step of providing a base substrate including a core layer and an insulating layer disposed on the core layer and a plasma step of plasma-treating an upper surface of the insulating layer. In the plasma step, an inert gas is applied as a process gas, and a plasma process condition index (Ipp value) defined by the following Equation 1 is 80 seconds or greater. A developed interfacial area ratio (Sdr value) of the upper surface of the insulating layer after completion of the plasma step is 50% or less. [Equation 1] Ipp=Rsb*H In Equation 1, Rsb is a ratio of bias power to source power applied during the plasma step, and His a processing time of the plasma step. In such a case, a redistribution layer having a fine pitch on the core layer may be more precisely implemented.

### CROSS-REFERENCE TO RELATED APPLICATION

This application claims the priority benefit under 35 USC § 119 (e) of U.S. Provisional Patent Application No. 63/721,549, filed on Nov. 17, 2024, the entire disclosure of which is incorporated herein by reference for all purposes.

### TECHNICAL FIELD

The present disclosure relates to a method of manufacturing a packaging substrate.

### BACKGROUND

In manufacturing electronic components, implementing a circuit on a semiconductor wafer is referred to as a front-end process (FE: Front-End), and assembling the wafer into a state usable in an actual product is referred to as a back-end process (BE: Back-End), which includes a packaging process.

Four core technologies that have enabled the rapid development of electronic products in recent years include semiconductor technology, semiconductor packaging technology, manufacturing process technology, and software technology. Although semiconductor technology has evolved in various ways such as micron or sub-nanometer line widths, over ten million cells, high-speed operation, and large heat dissipation, the technology for perfectly packaging such semiconductors has not been developed to a comparable degree. Accordingly, the electrical performance of a semiconductor may be determined by the packaging technology and the resulting electrical connection rather than the inherent performance of the semiconductor itself.

As materials for packaging substrates, ceramics or resins are used. In the case of ceramic substrates, it is difficult to mount high-performance, high-frequency semiconductor devices due to high resistivity or high dielectric constant. In the case of resin substrates, high-performance, high-frequency semiconductor devices can be mounted relatively easily, but there is a limitation in reducing the wiring pitch.

Recently, studies have been conducted on applying silicon or glass as materials for high-end packaging substrates. By forming through holes in a silicon or glass substrate and applying a conductive material to these through holes, the wiring length between the device and the motherboard can be shortened, and excellent electrical characteristics can be achieved.

### SUMMARY

A method of manufacturing a packaging substrate according to one embodiment of the present specification comprises:
a preparation step of providing a base substrate including a core layer and an insulating layer disposed on the core layer; and
a plasma step of plasma-treating an upper surface of the insulating layer to manufacture the packaging substrate.

In the plasma step, an inert gas is applied as a process gas, and a plasma process condition index (Ipp value) defined by the following Equation 1 is 80 seconds or greater.

$$Ipp = Rsb \times H \qquad [ Equation 1 ]$$

In Equation 1, Rsb is a ratio of bias power to source power applied during the plasma step, and His a processing time (seconds) of the plasma step.

A developed interfacial area ratio (Sdr value) of the upper surface of the insulating layer after completion of the plasma step is 50% or less.

The Sdr value may be 50% or less.

The Rsb value may be in a range of 0.05 to 3.

The bias power may be in a range of 50 W to 3,000 W.

The source power may be in a range of 500 W to 3,000 W.

The H value may be in a range of 80 seconds to 500 seconds.

The inert gas may be selected from the group consisting of Ne gas, Ar gas, Kr gas, Xe gas, Rn gas, and a combination thereof.

An ambient pressure in the plasma step may be greater than 0 mTorr and 10 m Torr or less.

The method of manufacturing a packaging substrate may further comprise a metal layer forming step of forming a metal layer on the upper surface of the insulating layer after completion of the plasma step.

An peeling strength of the metal layer to the upper surface of the insulating layer may be 300 gf/cm or greater.

The metal layer may include a first metal layer disposed on the upper surface of the insulating layer and a second metal layer disposed on the first metal layer.

The first metal layer may include any one selected from the group consisting of titanium, tungsten, tantalum, molybdenum, nickel, chromium, and a combination thereof.

The second metal layer may include copper.

A thickness ratio of the second metal layer to the first metal layer may be in a range of 1.2 to 15.

In the metal layer forming step, the first metal layer may be formed by sputtering.

The method of manufacturing a packaging substrate may further comprise an insulating layer patterning step of patterning the insulating layer using the metal layer as an etching mask.

### BRIEF DESCRIPTION OF THE DRAWINGS

FIG. 1 is a cross-sectional view of a base substrate prepared through a preparation step.

FIG. 2 is a cross-sectional view illustrating a metal layer prepared through a metal layer forming step of the present disclosure.

FIG. 3 is a cross-sectional view illustrating an insulating layer after completion of an insulating layer patterning step of the present disclosure.

FIG. 4A is an image of the upper surface of the insulating layer after plasma treatment in Experimental Example 1, measured by FE-SEM.

FIG. 4B is an image of the upper surface of the insulating layer after plasma treatment in Experimental Example 2, measured by FE-SEM.

FIG. 4C is an image of the upper surface of the insulating layer after plasma treatment in Experimental Example 3, measured by FE-SEM.

FIG. 4D is an image of the upper surface of the insulating layer after plasma treatment in Experimental Example 4, measured by FE-SEM.

FIG. 4E is an image of the upper surface of the insulating layer after plasma treatment in Experimental Example 5, measured by FE-SEM.

FIG. 4F is an image of the upper surface of the insulating layer after plasma treatment in Experimental Example 6, measured by FE-SEM.

FIG. 4G is an image of the upper surface of the insulating layer after plasma treatment in Experimental Example 7, measured by FE-SEM.

FIG. 4H is an image of the upper surface of the insulating layer after plasma treatment in Experimental Example 8, measured by FE-SEM.

### DETAILED DESCRIPTION

Hereinafter, embodiments will be described in detail with reference to the accompanying drawings so that those skilled in the art to which the present disclosure pertains may easily carry out the embodiments. However, the present disclosure may be implemented in various different forms and is not limited to the embodiments described herein. Throughout the specification, the same reference numerals are assigned to like elements.

Throughout the specification, the term “a combination thereof” included in a Markush-type expression means a mixture or combination of one or more selected from the group of components described in the Markush expression, and indicates that one or more selected from the group are included.

Throughout the specification, terms such as “first,” “second,” or “A,” “B,” and the like are used to distinguish between similar elements, and the singular form includes the plural form unless the context clearly indicates otherwise.

In the present specification, the term “-based” may mean that the compound or its derivative corresponding to “-” is included in the compound.

In the present specification, the expression “B is positioned on A” means that B is positioned directly on A or that B is positioned on A with another layer interposed therebetween, and is not limitedly interpreted as B being in direct contact with the surface of A.

In the present specification, the expression “A is connected to B” means that A and B are directly connected or that A and B are connected through another component therebetween, and unless otherwise specified, it is not limitedly interpreted as A and B being directly connected.

In the present specification, a singular expression is interpreted to include both singular and plural meanings unless otherwise described or unless the context clearly indicates otherwise.

In the present specification, the shapes, relative sizes, and angles of the components in the drawings are exemplary and may be exaggerated for the purpose of explanation, and the scope of rights is not limited to the drawings.

In the present specification, the expression that A and B are adjacent means that A and B are positioned in contact with each other or positioned close to each other without being in contact, and unless otherwise specified, it is not limitedly interpreted as A and B being positioned in contact with each other.

Unless otherwise described, the physical property values of the respective components in the packaging substrate are interpreted as values measured at room temperature, and the room temperature is 20° C. to 25° C.

During a process of forming a metal layer on an insulating layer through sputtering and pattern transfer, deposition defects of sputtering particles may occur in some regions of the upper surface of the insulating layer, or at least a part of a patterned metal layer may easily peel off from the insulating layer. Such phenomena may make it difficult to precisely transfer a metal layer pattern onto the insulating layer.

The inventors of the present disclosure have experimentally confirmed that, through the method of manufacturing a packaging substrate described below, deposition defects of sputtering particles on the upper surface of the insulating layer may be suppressed, and by implementing a fine pattern having excellent adhesion to the upper surface of the insulating layer, a redistribution layer having a fine pitch may be more precisely formed, thereby completing the present disclosure.

Hereinafter, the present disclosure will be described in detail.

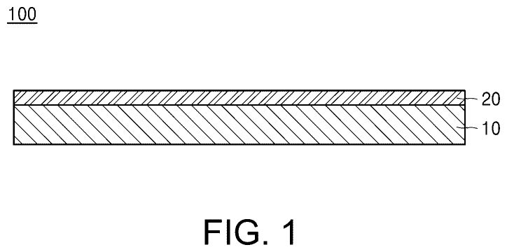

FIG. 1 is a cross-sectional view of a base substrate prepared through a preparation step. Hereinafter, the present disclosure will be described with reference to FIG. 1.

A method of manufacturing a packaging substrate according to the present disclosure includes a preparation step of preparing a base substrate including a core layer and an insulating layer disposed on the core layer, and a plasma step of plasma-treating an upper surface of the insulating layer to manufacture a packaging substrate.

### Preparation Step

In the preparation step, a base substrate (100) may be prepared.

The base substrate (100) may include a core layer (10). The core layer (10) has a substrate shape and may serve as a support layer in the packaging substrate. The core layer (10) is not limited as long as it can be applied in the field of packaging substrates. For example, the core layer (10) may be an organic substrate, a glass-fiber-impregnated substrate, a ceramic substrate, or a glass substrate.

A thickness of the core layer (10) may be 100 μm or greater. The thickness may be 200 μm or greater. The thickness may be 300 μm or greater. The thickness may be 3,000 μm or less. The thickness may be 2,000 μm or less. The thickness may be 1,000 μm or less. In this case, the core layer (10) may have mechanical properties suitable for application to a packaging substrate.

The base substrate (100) may include an insulating layer (20) disposed on the core layer (10).

In the preparation step, a base substrate (100) in which the insulating layer (20) has already been formed on the core layer (10) may be introduced. In the preparation step, the base substrate (100) may be prepared by forming the insulating layer (20) on the core layer (10).

The insulating layer (20) may be applicable as an insulating layer (20) that can be used in the field of packaging substrates. For example, an epoxy-based resin containing a filler may be applied as the insulating layer (20). For example, the insulating layer (20) may be formed using a build-up layer material such as ABF (Ajinomoto Build-up Film) manufactured by Ajinomoto Co., or an undercoat material, but is not limited thereto.

The insulating layer (20) may include a filler. The filler may include silica. The filler may be silica.

When forming the insulating layer (20) on the core layer (10), the insulating layer (20) may be formed by laminating and curing an uncured or semi-cured insulating film.

In the base substrate (100), a conductive layer (not shown) may be disposed between the core layer (10) and the insulating layer (20). The conductive layer may have a patterned shape. The conductive layer may be disposed in contact with an upper surface of the core layer (10). When another component is disposed between the conductive layer and the core layer (10), the conductive layer may be formed spaced apart from the upper surface of the core layer (10).

The insulating layer (20) may be disposed on the conductive layer. The insulating layer (20) may be formed to surround at least a part of the conductive layer. The insulating layer (20) and the conductive layer may be mixedly disposed on the core layer (10). The conductive layer having a patterned shape may be formed in an embedded form within the insulating layer (20).

### Plasma Step

In the method of manufacturing a packaging substrate of the present disclosure, an upper surface of the insulating layer (20) may be plasma-treated in the plasma step. When a metal layer is formed on the upper surface of the insulating layer (20) through a sputtering process, if the roughness characteristics of the upper surface of the insulating layer (20) are not controlled, a shadowing effect may occur in which sputtering particles are not uniformly deposited due to irregularities positioned on the upper surface of the insulating layer (20). Such an effect may act as one of the main factors that may interfere with precise implementation of the metal layer. When a conventional plasma treatment is performed on the upper surface of the insulating layer to remove the irregularities, process gas used for the plasma process may remain on the upper surface of the insulating layer (20), thereby reducing the adhesive strength between the insulating layer (20) and the metal layer.

In the present disclosure, an inert gas may be applied as a process gas in the plasma step, and a ratio between source power and bias power may be adjusted. Through this, the effect of the process gas on the adhesive force between the upper surface of the insulating layer (20) and the metal layer may be reduced, while providing an upper surface of the insulating layer (20) having a roughness characteristic suitable for implementing a fine pattern on the insulating layer (20).

A partial pressure of the inert gas relative to the total process gas may be 70% or greater. The partial pressure may be 80% or greater. The partial pressure may be 90% or greater. The partial pressure may be 99% or greater. The process gas may consist of an inert gas.

The inert gas may be selected from the group consisting of Ne gas, Ar gas, Kr gas, Xe gas, Rn gas, and a combination thereof. The inert gas may include Ar gas. The inert gas may be Ar gas.

In the plasma step, a plasma process condition index (Ipp value) of the following Equation 1 may be 80 seconds or greater.

$$Ipp = Rsb \times H \qquad [ Equation 1 ]$$

In Equation 1, Rsb is a ratio of bias power to source power applied during the plasma step, and His a processing time (seconds) of the plasma step.

In the present disclosure, the Ipp value may be controlled within a predetermined range as a process condition in the plasma step, thereby reducing a difference in etching rate between the insulating resin and the filler to a certain level or less during the plasma step. Through this, the frequency at which the filler protrudes from the upper surface of the insulating layer (20) after completion of the plasma step may be reduced, and the upper surface of the insulating layer may have a smoothness suitable for implementing a fine metal layer pattern.

The Ipp value in the plasma step may be 80 seconds or greater. The Ipp value may be 90 seconds or greater. The Ipp value may be 100 seconds or greater. The Ipp value may be 110 seconds or greater. The Ipp value may be 120 seconds or greater. The Ipp value may be 150 seconds or greater. The Ipp value may be 170 seconds or greater. The Ipp value may be 200 seconds or greater. The Ipp value may be 500 seconds or less. In this case, the filler may be sufficiently etched so that the insulating layer in the plasma step may have an upper surface suitable for implementing a fine metal layer pattern.

A ratio of bias power to source power applied in the plasma step may be in a range of 0.05 to 3. The ratio may be 0.1 or greater. The ratio may be 0.3 or greater. The ratio may be 0.5 or greater. The ratio may be 2.5 or less. The ratio may be 2 or less.

In this case, the influence of the process gas on the deterioration in adhesive strength between the insulating layer (20) and the metal layer may be effectively reduced, while the upper surface of the insulating layer (20) may have a roughness characteristic suitable for implementing a fine pattern.

The bias power may be in a range of 50 W to 3,000 W. The bias power may be 100 W or greater. The bias power may be 300 W or greater. The bias power may be 500 W or greater. The bias power may be 2,700 W or less. The bias power may be 2,500 W or less. The bias power may be 2,200 W or less. The bias power may be 2,000 W or less. The bias power may be 1,700 W or less. In this case, ions in a plasma state may have sufficient energy and collide with the upper surface of the insulating layer (20), thereby efficiently reducing the roughness of the upper surface of the insulating layer (20).

The source power may be in a range of 500 W to 3,000 W. The source power may be 600 W or greater. The source power may be 800 W or greater. The source power may be 2,700 W or less. The source power may be 2,500 W or less. The source power may be 2,200 W or less. The source power may be 2,000 W or less. The source power may be 1,700 W or less. In this case, a sufficient amount of plasma may be smoothly generated in an atmosphere in which the base substrate (100) is disposed, enabling surface treatment of the upper surface of the insulating layer (20).

An ambient pressure in the plasma step may be greater than 0 m Torr and 10 mTorr or less. The ambient pressure may be 1 m Torr or greater. The ambient pressure may be 8 m Torr or less. In this case, electrons may be accelerated above a certain level in the plasma atmosphere, and the process gas may be smoothly ionized.

The plasma step may be performed for 80 seconds to 500 seconds. The plasma step may be performed for 100 seconds or longer. The plasma step may be performed for 120 seconds or longer. The plasma step may be performed for 450 seconds or less. The plasma step may be performed for 400 seconds or less. The plasma step may be performed for 350 seconds or less. The plasma step may be performed for 300 seconds or less. In this case, the upper surface of the insulating layer (20) may have a roughness characteristic suitable for precisely implementing a fine pattern.

A developed interfacial area ratio (Sdr value) of the upper surface of the insulating layer after completion of the plasma step may be 50% or less.

Irregularities formed on the upper surface of the insulating layer may make it difficult to form a metal layer having a fine pattern shape or may reduce the adhesive strength of the metal pattern layer to the insulating layer. In the present disclosure, the Sdr value of the upper surface of the insulating layer may be controlled within a specific range through the plasma step. Through this, a fine metal layer pattern designed in advance on the insulating layer may be implemented more accurately, and the pattern may have stable adhesion to the upper surface of the insulating layer.

The Sdr value of the upper surface of the insulating layer may be measured according to ISO 25178 standards. Specifically, five regions having a width of 300 μm and a length of 300 μm may be arbitrarily selected on the upper surface of the insulating layer. The Sdr value may be measured for each of the selected regions, and an average value of the measured values may be calculated as the Sdr value of the upper surface of the insulating layer.

The developed interfacial area ratio (Sdr value) of the upper surface of the insulating layer after completion of the plasma step may be 50% or less. The Sdr value may be 45% or less. The Sdr value may be 40% or less. The Sdr value may be 35% or less. The Sdr value may be 30% or less. The Sdr value may be 25% or less. The Sdr value may be 20% or less. The Sdr value may be 15% or less. The Sdr value may be 1% or greater. In this case, interference with precise implementation of a fine metal pattern layer due to the filler may be effectively suppressed.

### Metal Layer Forming Step

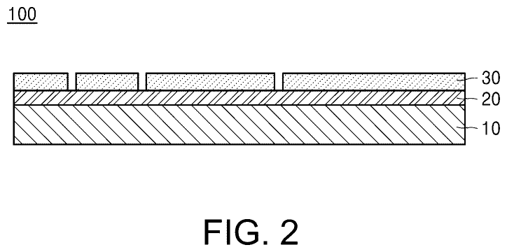

FIG. 2 is a cross-sectional view illustrating a metal layer prepared through a metal layer forming step of the present disclosure. Hereinafter, the present disclosure will be described with reference to FIG. 2.

The descriptions of the base substrate (100), the core layer (10), and the insulating layer (20) described with reference to FIG. 1 may be equally applied here. The following will focus on differences.

The method of manufacturing a packaging substrate according to the present disclosure may further include a metal layer forming step of forming a metal layer (30) on an upper surface of the insulating layer (20) after completion of the plasma step.

The metal layer (30) may be a conductive layer that transmits an electrical signal. The metal layer (30) may be an etching mask for patterning the insulating layer (20) disposed under the metal layer (30).

The metal layer (30) may include a first metal layer (not shown) disposed on the upper surface of the insulating layer (20) and a second metal layer (not shown) disposed on the first metal layer. The first metal layer may be disposed in contact with the upper surface of the insulating layer (20). The second metal layer may be disposed in contact with an upper surface of the first metal layer.

The first metal layer may include any one selected from the group consisting of titanium, tungsten, tantalum, molybdenum, nickel, chromium, and a combination thereof. The first metal layer may include 90 at % or greater of any one selected from the group consisting of titanium, tungsten, tantalum, molybdenum, nickel, chromium, and a combination thereof. The first metal layer may include 95 at % or greater of any one selected from the same group. The first metal layer may include 100 at % or less of any one selected from the same group. The first metal layer may help the metal layer (30) to be stably fixed on the upper surface of the insulating layer (20).

The second metal layer may include copper. The second metal layer may include 90 at % or greater of copper. The second metal layer may include 95 at % or greater of copper. The second metal layer may include 100 at % or less of copper. The second metal layer may impart etching resistance suitable for patterning the insulating layer (20) to the metal layer (30).

The metal layer forming step may include a first metal layer forming process of forming the first metal layer disposed on the upper surface of the insulating layer (20), and a second metal layer forming process of forming the second metal layer disposed on the upper surface of the first metal layer.

In the metal layer forming step, the first metal layer may be formed by sputtering. When the first metal layer is formed by sputtering on the upper surface of the insulating layer (20) after completion of the plasma step of the present disclosure, the shadowing effect may be suppressed, thereby enabling the metal layer (30) to have a more uniform thickness distribution and excellent adhesion characteristics. The metal layer (30) having such characteristics may contribute to precise patterning of the insulating layer (20).

In the metal layer forming step, the second metal layer disposed on the upper surface of the first metal layer may be formed by sputtering. In this case, an anchor effect may occur between the first metal layer and the second metal layer, thereby forming stable adhesive strength between the first and second metal layers having different compositions.

In the metal layer forming step, a metal included in the first metal layer may be sputtered onto the upper surface of the insulating layer (20) to form the first metal layer. In the metal layer forming step, a metal included in the second metal layer may be sputtered onto the upper surface of the first metal layer to form the second metal layer.

An peeling strength of the metal layer (30) to the upper surface of the insulating layer (20) may be 300 gf/cm or greater. The peeling strength may be 350 gf/cm or greater. The peeling strength may be 400 gf/cm or greater. The peeling strength may be 450 gf/cm or greater. The peeling strength may be 500 gf/cm or greater. The peeling strength may be 550 gf/cm or greater. The peeling strength may be 600 gf/cm or greater. The peeling strength may be 1,000 gf/cm or less. In this case, the metal layer (30) may be stably fixed on the insulating layer (20).

The peeling strength may be measured as follows. After cutting the metal layer (30) on the insulating layer (20) into a strip having a width of 10 mm and a length of 100 mm, one end of the cut metal layer (30) in the longitudinal direction is pulled at an angle of 90° with respect to the upper surface of the insulating layer (20) to measure the peeling strength.

The present disclosure may control the thickness ratio of the second metal layer to the first metal layer within a predetermined range. Through this, during manufacturing or use of the packaging substrate, the metal layer (30) may be stably fixed to the insulating layer (20).

A thickness ratio of the second metal layer to the first metal layer may be in a range of 1.2 to 15. The ratio may be 1.5 or greater. The ratio may be 2 or greater. The ratio may be 2.5 or greater. The ratio may be 3 or greater. The ratio may be 12 or less. The ratio may be 10 or less. The ratio may be 8 or less. In this case, the ratio may contribute to precise patterning of the insulating layer (20).

A thickness of the metal layer (30) may be 200 nm or greater. The thickness may be 250 nm or greater. The thickness may be 300 nm or greater. The thickness may be 1,000 nm or less. The thickness may be 800 nm or less. The thickness may be 600 nm or less.

A thickness of the second metal layer may be 150 nm or greater. The thickness may be 200 nm or greater. The thickness may be 250 nm or greater. The thickness may be 800 nm or less. The thickness may be 600 nm or less. The thickness may be 400 nm or less.

In this case, the metal layer (30) may have a smooth signal transmission function. In addition, when the metal layer (30) is used as an etching mask, the metal layer (30) may have etching resistance sufficient to function as the etching mask.

A thickness of the first metal layer may be 20 nm or greater. The thickness may be 30 nm or greater. The thickness may be 150 nm or less. The thickness may be 120 nm or less. The thickness may be 100 nm or less. In this case, the metal layer (30) may help ensure stable fixation to the insulating layer (20).

The metal layer forming step may further include a metal layer patterning process of patterning the metal layer (30). The patterned metal layer (30) may be a conductive layer pattern for transmitting electrical signals in the packaging substrate. The patterned metal layer (30) may have a pattern to be transferred to the insulating layer (20).

A method of patterning the metal layer (30) may not be limited as long as it is a method generally applied in the field of packaging substrates. For example, a dry film resist layer may be laminated and cured on the metal layer (30), the resist layer may be patterned and developed, and then the metal layer (30) may be patterned by dry etching or wet etching using the patterned resist layer as a mask.

### Insulating Layer Patterning Step

The method of manufacturing a packaging substrate according to the present disclosure may further include an insulating layer patterning step of patterning the insulating layer (20) using the metal layer (30) as an etching mask.

In the insulating layer patterning step, the insulating layer (20) may be plasma-etched using the metal layer (30) as an etching mask, thereby implementing the patterned insulating layer (20). The insulating layer (20) may be plasma-etched by a plasma etching process that may be generally applied in the field of packaging substrates.

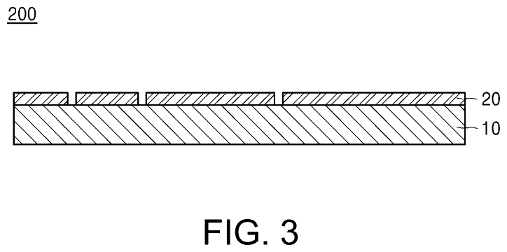

FIG. 3 is a cross-sectional view illustrating the insulating layer after completion of the insulating layer patterning step of the present disclosure. Hereinafter, the present disclosure will be described with reference to FIG. 3.

The descriptions of the core layer (10) and the insulating layer (20) described with reference to FIGS. 1 and 2 may be equally applied here. The following will focus on differences.

After completion of the plasma etching of the insulating layer (20), the metal layer disposed on the patterned insulating layer (20) may be removed to manufacture a packaging substrate (200). The metal layer may be removed by wet etching or dry etching.

### Other Steps

The method of manufacturing a packaging substrate according to the present disclosure may plasma-treat an upper surface of the insulating layer (20) after completion of an insulating layer patterning step. Through this, a surface roughness of the upper surface of the insulating layer (20) may be reduced to a certain level or less, and an electrically conductive layer having excellent thickness uniformity and adhesion uniformity on the insulating layer (20) may be implemented.

The plasma treatment on the upper surface of the insulating layer (20) after completion of the insulating layer patterning step may be performed under the same conditions and method as the plasma step described above. A description of the plasma treatment on the upper surface of the insulating layer (20) after completion of the insulating layer patterning step is omitted since it is duplicated with the above description.

The method of manufacturing a packaging substrate according to the present disclosure may form an electrically conductive layer (not shown) on the insulating layer (20) after completion of the insulating layer patterning step.

The electrically conductive layer may include a seed layer and a conductor layer disposed on the seed layer. The conductor layer may be disposed in contact with the seed layer.

The seed layer may include any one selected from the group consisting of titanium, tungsten, tantalum, molybdenum, nickel, chromium, and a combination thereof. The seed layer may include a first seed layer and a second seed layer disposed on the first seed layer. The first seed layer may include any one selected from the group consisting of titanium, tungsten, tantalum, molybdenum, nickel, chromium, and a combination thereof. The second seed layer may include a metal element identical to that applied to the conductor layer. The second seed layer may include copper. The seed layer having such a structure and composition may help the electrically conductive layer to have excellent adhesion to the patterned insulating layer (20). The conductor layer may include copper.

When forming an electrically conductive layer on the patterned insulating layer (20), the electrically conductive layer may be formed by a dry method or a wet method.

The dry method is a method in which sputtering is performed on a region where the electrically conductive layer is to be disposed on the patterned insulating layer (20) to form a seed layer, and plating is performed on a region where the seed layer is formed to form the electrically conductive layer. During formation of the seed layer, a metal selected from the group consisting of titanium, tungsten, tantalum, molybdenum, nickel, chromium, and a combination thereof may be sputtered to form a first seed layer, and copper may be sputtered on the first seed layer to form a second seed layer.

The wet method is a method in which a primer is treated on a portion where formation of the electrically conductive layer is required, followed by metal plating. The primer may include a compound having a functional group such as an amine. Depending on a degree of intended adhesion strength, the primer may include both a compound having a functional group such as an amine and a silane coupling agent. When applying a silane coupling agent, a primer layer may be formed by pre-treating a surface to be primer-treated with the silane coupling agent and then coating a compound having an amine group on the pretreated region.

After forming the seed layer or the primer layer, the electrically conductive layer may be prepared by plating a metal to form the conductor layer. When forming the electrically conductive layer, copper plating may be applied, but is not limited thereto. Prior to metal plating, a portion in the seed layer or the primer layer where formation of the electrically conductive layer is not required may be inactivated, or a portion where formation of the electrically conductive layer is required may be activated, followed by plating. As a method for activation or inactivation treatment, light irradiation treatment such as irradiation of laser with a specific wavelength or chemical treatment may be applied. However, without applying activation or inactivation treatment, the metal plating may be performed, and then the electrically conductive layer may be patterned by etching the electrically conductive layer according to a pre-designed shape.

If necessary, the method of manufacturing a packaging substrate according to the present disclosure may further include a step of forming an insulating layer disposed on the electrically conductive layer and another electrically conductive layer disposed on the insulating layer. If necessary, the step of forming the electrically conductive layer according to the present disclosure may further include a step of forming an insulating layer disposed below the core layer (10) and another electrically conductive layer disposed below the insulating layer. The insulating layer and the electrically conductive layer may be prepared in the same manner as described above.

If necessary, an upper terminal or the like may be additionally formed on an upper portion and/or lower side of the packaging substrate, and/or bumps may be additionally formed on a lower portion of the packaging substrate. The bumps may be arranged in a predetermined shape below a redistribution layer which includes layers of the insulating layer and the electrically conductive layer disposed below the core layer (10). For example, the bumps may be arranged on a portion of the lower surface of the packaging substrate to be in contact with a main board or the like.

Hereinafter, the present disclosure will be described in more detail through specific examples. The following examples are merely provided for better understanding of the present disclosure, and the scope of the present disclosure is not limited thereto.

### Manufacturing Example: Manufacture of Packaging Substrate

Experimental Example 1: A glass substrate having a thickness of 0.5 mm was prepared as a core layer. A base substrate was prepared by laminating and curing a build-up film (ABF GL103) having a thickness of 20 μm on one surface of the core layer to form an insulating layer.

After the base substrate was loaded into a chamber, plasma treatment was performed on the upper surface of the insulating layer for 60 seconds. During desmearing, argon gas was introduced as a process gas into the chamber, an ambient pressure in the chamber was set to 2 mTorr, a source power was set to 1,000 W, and a bias power was set to 700 W.

A metal layer was formed on the upper surface of the insulating layer after completion of the plasma treatment to manufacture a packaging substrate. The metal layer was prepared by forming a first metal layer, which is a titanium layer having a thickness of 50 nm, by sputtering, and forming a second metal layer, which is a copper layer having a thickness of 300 nm, on the first metal layer by sputtering. A dry film resist layer was formed on the metal layer, and an electrode pattern having a size of 2×2 was developed on the resist layer. Thereafter, the metal layer was wet-etched with a sulfuric acid-hydrogen peroxide solution to transfer a pattern onto the metal layer, and the resist layer was removed to prepare a packaging substrate having a patterned metal layer on the insulating layer.

Experimental Example 2: A packaging substrate was manufactured under the same conditions as in Experimental Example 1, except that the plasma treatment on the upper surface of the insulating layer was performed for 80 seconds.

Experimental Example 3: A packaging substrate was manufactured under the same conditions as in Experimental Example 1, except that the plasma treatment on the upper surface of the insulating layer was performed for 100 seconds.

Experimental Example 4: A packaging substrate was manufactured under the same conditions as in Experimental Example 1, except that the plasma treatment on the upper surface of the insulating layer was performed for 160 seconds.

Experimental Example 5: A packaging substrate was manufactured under the same conditions as in Experimental Example 1, except that the source power was set to 800 W and the bias power was set to 1,120 W.

Experimental Example 6: A packaging substrate was manufactured under the same conditions as in Experimental Example 5, except that the plasma treatment on the upper surface of the insulating layer was performed for 80 seconds.

Experimental Example 7: A packaging substrate was manufactured under the same conditions as in Experimental Example 5, except that the plasma treatment on the upper surface of the insulating layer was performed for 100 seconds.

Experimental Example 8: A packaging substrate was manufactured under the same conditions as in Experimental Example 5, except that the plasma treatment on the upper surface of the insulating layer was performed for 160 seconds.

Experimental Example 9: A packaging substrate was manufactured under the same conditions as in Experimental Example 1, except that the source power was set to 1,000 W, the bias power was set to 1,400 W, and the plasma treatment on the upper surface of the insulating layer was performed for 80 seconds.

Experimental Example 10: A packaging substrate was manufactured under the same conditions as in Experimental Example 9, except that the plasma treatment on the upper surface of the insulating layer was performed for 120 seconds.

Experimental Example 11: A packaging substrate was manufactured under the same conditions as in Experimental Example 9, except that the plasma treatment on the upper surface of the insulating layer was performed for 160 seconds.

Experimental Example 12: A packaging substrate was manufactured under the same conditions as in Experimental Example 1, except that the source power was set to 2,000 W, the bias power was set to 100 W, and the plasma treatment on the upper surface of the insulating layer was performed for 120 seconds.

The process conditions for each experimental example are shown in Table 1 below.

### Evaluation Example: Evaluation of Peeling Strength of Metal Layer with Respect to Insulating Layer

In the manufacturing process of each packaging substrate according to the respective experimental examples, a metal layer before patterning was cut into a size of 10 mm in width and 100 mm in length, and one end in the longitudinal direction of the metal layer was pulled upward at a 90° angle with respect to the upper surface of the packaging substrate to measure a peeling strength of the metal layer with respect to the insulating layer.

The evaluation results for each experimental example are shown in Table 2 below.

### Evaluation Example: Evaluation of Surface Shape of Insulating Layer after Plasma Treatment

In the manufacturing process of each packaging substrate according to the respective experimental examples, after plasma treatment of the insulating layer and before forming the metal layer, an image of the upper surface of the insulating layer was measured using a Field Emission Scanning Electron Microscope (FE-SEM). As a result of measurement, in a case where a convex portion derived from a filler was not observed, the result was evaluated as “Pass”, and in a case where the convex portion was observed, the result was evaluated as “Fail.”

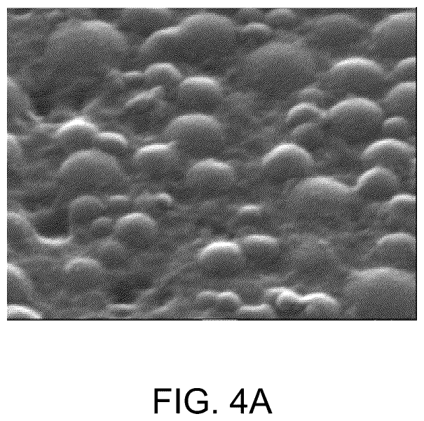

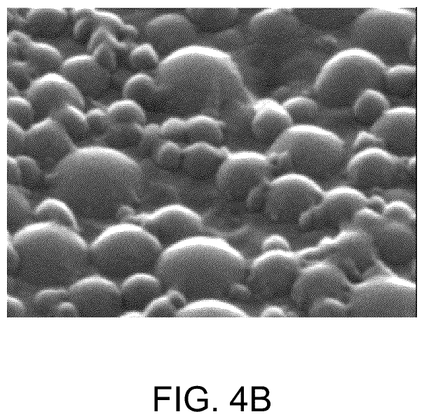

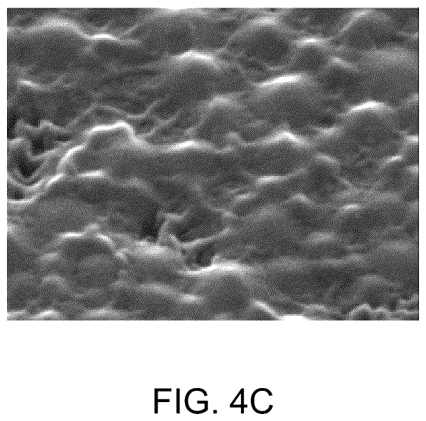

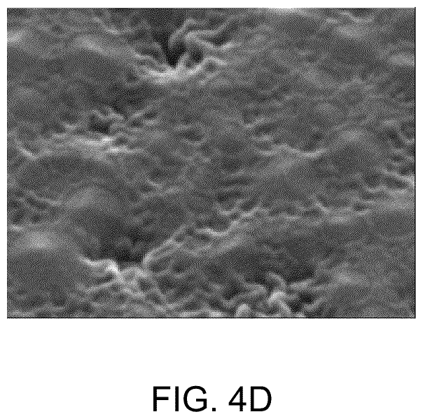

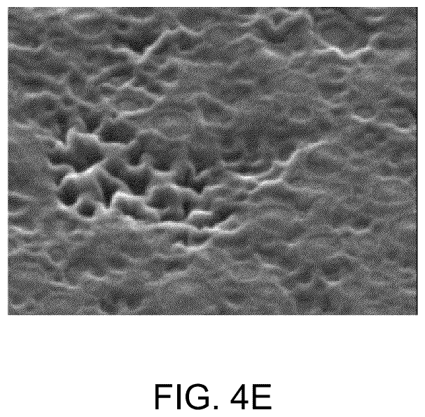

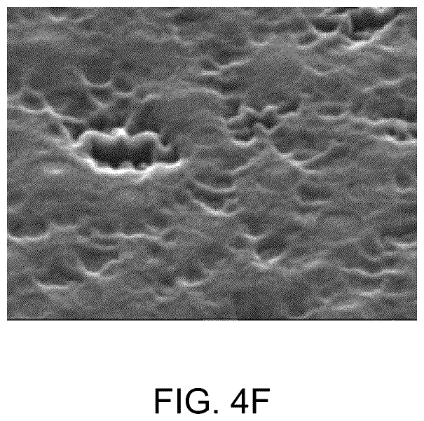

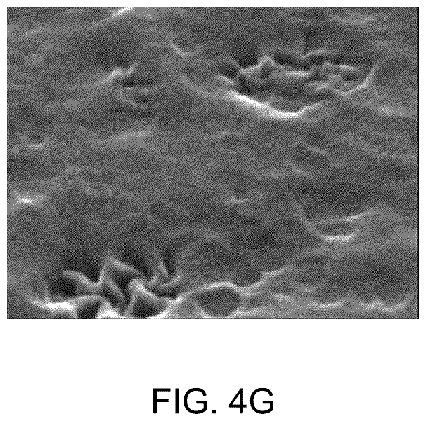

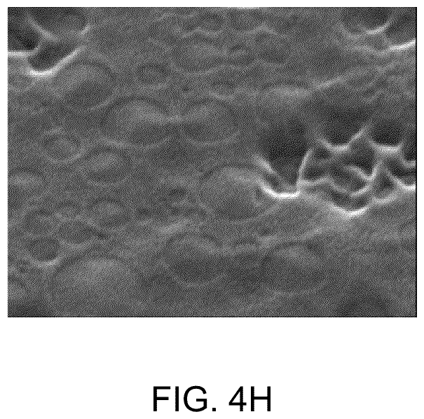

The evaluation results for each experimental example are shown in Table 2 below. In addition, images of the upper surface of the insulating layer in Experimental Examples 1 to 8 measured with FE-SEM are shown in FIGS. 4A to 4H.

### Evaluation Example: Measurement of Sdr Value of Upper Surface of Insulating Layer

In the manufacturing process of each packaging substrate according to the respective experimental examples, after completion of plasma treatment and before forming the metal layer, an Sdr value of the upper surface of the insulating layer was measured according to the standard ISO 25178. Specifically, a region of 300 μm in width and 300 μm in length was arbitrarily selected five times on the upper surface of the insulating layer. The Sdr value was measured for each of the regions, and an average value of the measured values was calculated as the Sdr value for each experimental example.

The measurement results for each experimental example are shown in Table 2 below.

### Evaluation Example: Pattern Inspection Through Microscope

A metal pattern layer formed on the upper surface of each packaging substrate according to the respective experimental examples was observed with an optical microscope. As a result of the observation, when no short circuit of the metal pattern layer was observed, the result was evaluated as “Pass,” and when a short circuit was observed, the result was evaluated as “Fail.”

The evaluation results for each experimental example are shown in Table 2 below.

TABLE 1

| | | | | | | Ambient |
|---|---|---|---|---|---|---|
| | | | | Source | Bias | Pressure in |
| | | | H | Power | Power | Chamber |
| | Ipp(s) | Rsb | (s) | (W) | (W) | (mTorr) |
| Experimental | 42 | 0.7 | 60 | 1000 | 700 | 2 |
| Example 1 | | | | | | |
| Experimental | 56 | 0.7 | 80 | 1000 | 700 | 2 |
| Example 2 | | | | | | |
| Experimental | 70 | 0.7 | 100 | 1000 | 700 | 2 |
| Example 3 | | | | | | |
| Experimental | 112 | 0.7 | 160 | 1000 | 700 | 2 |
| Example 4 | | | | | | |
| Experimental | 84 | 1.4 | 60 | 800 | 1120 | 2 |
| Example 5 | | | | | | |
| Experimental | 112 | 1.4 | 80 | 800 | 1120 | 2 |
| Example 6 | | | | | | |
| Experimental | 140 | 1.4 | 100 | 800 | 1120 | 2 |
| Example 7 | | | | | | |
| Experimental | 224 | 1.4 | 160 | 800 | 1120 | 2 |
| Example 8 | | | | | | |
| Experimental | 112 | 1.4 | 80 | 1000 | 1400 | 2 |
| Example 9 | | | | | | |
| Experimental | 168 | 1.4 | 120 | 1000 | 1400 | 2 |
| Example 10 | | | | | | |
| Experimental | 224 | 1.4 | 160 | 1000 | 1400 | 2 |
| Example 11 | | | | | | |
| Experimental | 6 | 0.05 | 120 | 2000 | 100 | 2 |
| Example 12 | | | | | | |
| Experimental | 80.4 | 0.67 | 120 | 1500 | 1000 | 2 |
| Example 13 | | | | | | |

TABLE 2

| | | Evaluation of | | |
|---|---|---|---|---|
| | | Surface Shape | | Microscopic |
| | PEEL | of Insulating | | Pattern |
| | (gf/cm) | Layer | Sdr(%) | Inspection |
| Experimental | 679 | Fail | 150 | Fail |
| Example 1 | | | | |
| Experimental | 484 | Fail | 280 | Fail |
| Example 2 | | | | |
| Experimental | 636 | Fail | 75 | Fail |
| Example 3 | | | | |
| Experimental | 585 | Pass | 25 | Pass |
| Example 4 | | | | |
| Experimental | 411 | Pass | 41 | Pass |
| Example 5 | | | | |
| Experimental | 458 | Pass | 30 | Pass |
| Example 6 | | | | |
| Experimental | 458 | Pass | 28 | Pass |
| Example 7 | | | | |
| Experimental | 581 | Pass | 20 | Pass |
| Example 8 | | | | |
| Experimental | 581 | Pass | 20 | Pass |
| Example 9 | | | | |
| Experimental | 487 | Pass | 15 | Pass |
| Example 10 | | | | |
| Experimental | 649 | Pass | 10 | Pass |
| Example 11 | | | | |
| Experimental | 214 | Fail | 165 | Fail |
| Example 12 | | | | |
| Experimental | 747 | Pass | 22 | Pass |
| Example 13 | | | | |

In Table 2, in the cases of Experimental Examples 4 to 11 and 13, in which the Sdr value, the source power, the bias power, and the plasma treatment time were controlled within the range defined in the present disclosure, a value of 400 gf/cm or greater was shown in the evaluation of the peeling strength of the metal layer, and “Pass” was evaluated in both the evaluation of the surface shape of the insulating layer and the microscopic pattern inspection. In contrast, in the cases of Experimental Examples 1 to 3 and 12, “Fail” was evaluated in the evaluation of the surface shape of the insulating layer and the microscopic pattern inspection.

The preferred embodiments of the present invention have been described in detail above; however, the scope of the present invention is not limited thereto, and various modifications and improved forms using the basic concept of the present invention defined in the following claims by those skilled in the art also belong to the scope of the present invention.

What is claimed is:

1. A method of manufacturing a packaging substrate, the method comprising:
a preparation step of providing a base substrate including a core layer and an insulating layer disposed on the core layer; and
a plasma step of plasma-treating an upper surface of the insulating layer,
wherein, in the plasma step, an inert gas is applied as a process gas, and a plasma process condition index (Ipp value) defined by the following Equation 1 is 80 seconds or greater,
and a developed interfacial area ratio (Sdr value) of the upper surface of the insulating layer after completion of the plasma step is 50% or less:
$$Ipp = Rsb \times H \qquad [ Equation 1 ]$$
wherein Rsb is a ratio of bias power to source power applied during the plasma step, and His a processing time (seconds) of the plasma step.

2. The method of claim 1,
wherein the Sdr value is 30% or less.

3. The method of claim 1,
wherein the Rsb value is in a range of 0.05 to 3.

4. The method of claim 1,
wherein the bias power is in a range of 50 W to 3,000 W.

5. The method of claim 1,
wherein the source power is in a range of 500 W to 3,000 W.

6. The method of claim 1,
wherein the H value is in a range of 80 seconds to 500 seconds.

7. The method of claim 1,
wherein the inert gas is selected from the group consisting of Ne gas, Ar gas, Kr gas, Xe gas, Rn gas, and a combination thereof.

8. The method of claim 1,
wherein an ambient pressure in the plasma step is greater than 0 mTorr and 10 mTorr or less.

9. The method of claim 1,
further comprising a metal layer forming step of forming a metal layer on the upper surface of the insulating layer after completion of the plasma step,
wherein a peeling strength of the metal layer to the upper surface of the insulating layer is 300 gf/cm or greater.

10. The method of claim 9,
wherein the metal layer includes a first metal layer disposed on the upper surface of the insulating layer and a second metal layer disposed on the first metal layer,
wherein the first metal layer includes any one selected from the group consisting of titanium, tungsten, tantalum, molybdenum, nickel, chromium, and a combination thereof,
wherein the second metal layer includes copper,
a thickness ratio of the second metal layer to the first metal layer is in a range of 1.2 to 15, and
wherein the first metal layer is formed by sputtering in the metal layer forming step.

11. The method of claim 9,
further comprising an insulating layer patterning step of patterning the insulating layer using the metal layer as an etching mask.
